(19) United States
(12) Patent Application Publication
(10) Pub. No.: US 2001/0023132 A1
(43) Pub. Date: Sep. 20, 2001

(54) METHOD FOR CONTROLLING CRITICAL DIMENSION OF CONTACT OPENING

(76) Inventors: TONG-YU CHEN, HSINCHU (TW); CHAN-LON YANG, TAIPEI (TW)

Correspondence Address: DANIEL R MCCLURE, THOMAS KAYDEN HORSTEMEYER & RISLEY LLP, SUITE 1500, 100 GALLERIA PARKWAY N W, ATLANTA, GA, 30339

(21) Appl. No.: 09/383,031

(22) Filed: Aug. 25, 1999

(51) Int. Cl. H01L 21/302; H01L 21/461

(52) U.S. Cl. 438/706

(57) ABSTRACT

A method for controlling the critical dimension of a contact opening in a dielectric layer. A substrate has a dielectric layer formed thereon. A hard mask layer is formed over the dielectric layer. A photosensitive layer is formed over the hard mask layer. The photosensitive layer is patterned to expose a portion of the hard mask layer inside a desired contact opening region. A first etching operation is carried out to remove the hard mask layer within the contact opening region so that a portion of the dielectric layer is exposed. A second etching operation is carried out to remove the dielectric layer within the contact opening region, thereby forming the contact opening.

### BACKGROUND OF THE INVENTION

1. Field of Invention

The present invention relates to a method for controlling the critical dimension of an opening. More particularly, the present invention relates to a method for controlling the critical dimension near the top of a contact opening.

2. Description of Related Art

In the fabrication of integrated circuits, proper control of critical dimensions is very important. As the level of integration continues to increase, any minor error in one of the critical dimensions can often result in a big decrease in the reliability of a device or even device malfunction.

At present, most large-scale integrated circuits employ a multi-level metal interconnect design with neighboring interconnect layers isolated from each other by a dielectric layer. Metallic interconnects in different layers are electrically connected by a conductive plug. The conductive plug is formed by etching out a contact opening in the dielectric layer, and then filling the opening with a conductive material.

FIG. 1 is a schematic cross-sectional view showing a conventional contact opening. As shown in FIG. 1, a substrate 100 having semiconductor devices (not shown in the figure) or metallic interconnect structures (also not shown in the figure) thereon is provided. An oxide layer 102 is formed over the substrate, and a photoresist layer 104 is formed over the oxide layer 102. The photoresist layer 104 is patterned to expose the oxide layer 102 inside a contact opening region 106. Using the patterned photoresist layer 104 as a mask, the exposed oxide layer 106 is anisotropically etched by remove a portion of the oxide inside the contact opening region 106, thereby forming a contact opening 108.

To form the patterned photoresist layer 104 in the aforementioned method, the original photoresist layer 104 has to be exposed to light and subsequently developed. However, light emitted from a light source may be diffracted. Some of the diffracted light rays may be redirected towards the edge of the desired pattern. Consequently, the developed photoresist layer is likely to be thinner towards the edge of the pattern. When the oxide layer 102 is etched to form the contact opening 108, a portion of the photoresist layer 104 is also removed. With a thinner photoresist layer near the edge of the pattern, a portion of the oxide layer 102 outside the exposed contact opening region 106 may also be etched after the thin photoresist layer near the edge is completely removed. Ultimately, the upper end of the contact opening 108 is widened to a dimension 110 beyond the desired range. Since the dimension 110 of the contact opening 108 is quite critical for highly integrated circuits, any deviation from the critical dimension may lead to a large leakage current or a bridging connection with a neighboring device.

Although this widening of contact opening can be reduced somewhat by forming a thicker photoresist layer, difficulties in controlling depth of focus (DOF) can result in a lower resolution of the light shining onto the photoresist layer. Such lowering of light resolution often leads to a deterioration of the critical dimensions in a patterned photoresist layer.

### SUMMARY OF THE INVENTION

The present invention provides a method for controlling the critical dimension near the top of a contact opening so that various device problems caused by a wide opening can be avoided.

To achieve these and other advantages and in accordance with the purpose of the invention, as embodied and broadly described herein, the invention provides a method for controlling the critical dimension of a contact opening. A substrate having semiconductor devices or metallic interconnects thereon is provided. A dielectric layer such as an oxide layer is formed over the substrate. A titanium/titanium nitride composite layer or a hard mask assembly is formed over the dielectric layer. A photosensitive layer is formed over the hard mask layer. The photosensitive layer is patterned to expose a portion of the hard mask layer inside a contact opening region. A first etching operation is carried out to remove the hard mask layer inside the contact opening region. A second etching operation is next carried out to remove the exposed dielectric layer so that a contact opening is formed.

The hard mask layer serves as an etching mask during the second etching operation. The hard mask layer is able to protect the dielectric layer near the fringe of the contact opening during the second etching operation because etching selectivity between the hard mask layer and the dielectric layer is rather high. Hence, although the photoresist layer is thinner near the edge of the contact opening region so that the photoresist layer may be completely removed there, the hard mask can still protect the dielectric layer during the second etching operation. Since etching of the dielectric layer at the outer edge of the contact opening region is prevented, the critical dimension at the top of the contact opening falls within the desired range.

In addition, the hard mask layer is made from an etch-resistance material. Therefore, even after the hard mask layer has been etched by etchants during the second etching operation for quite some time, the dielectric layer outside the contact opening region is still well protected. Hence, processing window for the second stage etching operation is wider.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic cross-sectional view showing a conventional contact opening;

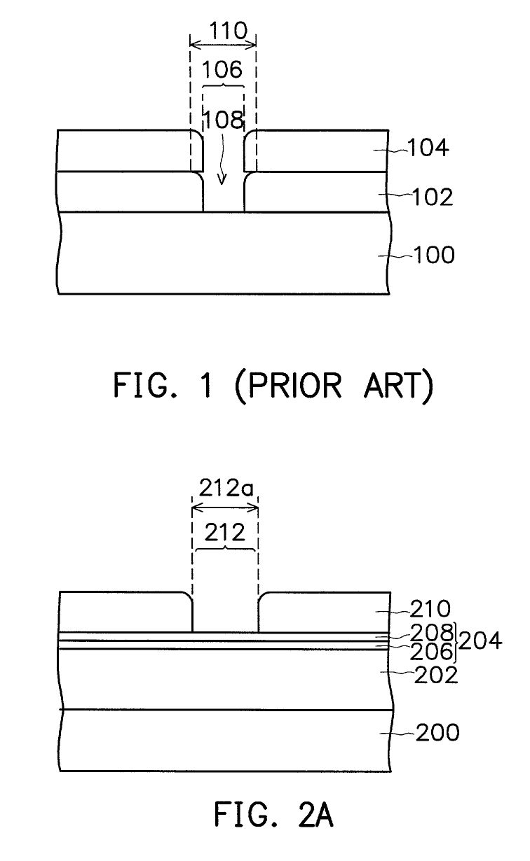

FIGS. 2A through 2C are schematic cross-sectional views showing the progression of manufacturing steps for controlling the critical dimension of a contact opening according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

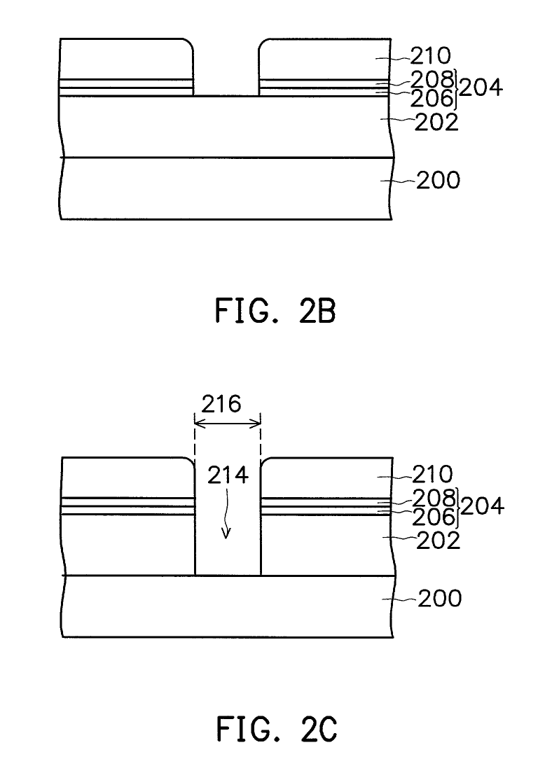

FIGS. 2A through 2C are schematic cross-sectional views showing the progression of manufacturing steps for controlling the critical dimension of a contact opening according to one preferred embodiment of this invention.

As shown in FIG. 2A, a substrate 200 having semiconductor devices (not shown in the figure) or metallic interconnect structures (also not shown in the figure) thereon is provided. A dielectric layer 202 is formed over the substrate 200. The dielectric layer 202 is an oxide layer, for example. A hard mask layer 204 is formed over the dielectric layer 202. The hard mask layer 204 can be, for example, a titanium layer or a titanium nitride layer, and can even be a composite layer of titanium and titanium nitride. For example, the hard mask layer 204 in FIG. 2A is a composite layer comprising a titanium layer 206 and a titanium nitride layer 208. The titanium layer 206 has a thickness preferably between about 100 Å and 200 Å and the titanium nitride layer has a thickness preferably of between about 200 Å and 400 Å.

A photosensitive layer 210 is formed over the hard mask layer 204. The photosensitive layer 210 is patterned to expose a portion of the hard mask layer 204 in a contact opening region 212. The photosensitive layer 210 can be formed, for example, by the steps of coating a photoresist layer over the substrate 200, performing a soft baking operation, exposing the layer to light, developing the photoresist layer and hard baking the photoresist layer. One characteristic of the photosensitive material is the ease of patterning a photosensitive layer using conventional photolithographic techniques. However, some of the light from a light source may be diffracted during photoexposure. Therefore, a thinner photosensitive layer 210 is likely to form around the edge of the pattern.

As shown in FIG. 2B, with the patterned photosensitive layer 210 serving as an etching mask, a first etching operation is carried out to remove the hard mask layer 204 inside the contact opening region 212. The first etching operation is, for example, an anisotropic etching operation performed at a pressure of between about 10 and 30 mT using gaseous reactants that include C₄F₈ with a flow rate of between about 10 to 30 sccm, nitrogen with a flow rate of between about 10 and 40 sccm and argon with a flow rate of between about 200 and 500 sccm.

As shown in FIG. 2C, a second etching operation is carried out to remove the dielectric layer 202 inside the contact opening region 212, thereby forming a contact opening 214. Critical dimension 216 near the top of the contact opening 214 is identical to the width 212a at the bottom of the contact opening 212 in the patterned photoresist layer 210. In the second etching operation, the patterned photosensitive layer 210 and the hard mask layer 204 are used as an etching mask. The dielectric layer 202 is anisotropically etched at a pressure of between about 40 and 60 mT using gaseous reactants that include CH₂F₂ with a flow rate of between about 30 and 60 sccm, nitrogen with a flow rate of between about 30 and 70 sccm and oxygen with a flow rate of between about 50 and 200 sccm.

In the second etching operation, some of the photosensitive material may be etched away. Sometimes, a portion of the photosensitive layer 210 may even be completely removed so that the underlying hard mask layer 204 is exposed. Because the hard mask layer 204 has a relatively high etching selectivity with respect to the dielectric layer 202, the dielectric layer 202 just outside the edge of the contact opening 214 is well protected. Hence, utilizing the two separate etching operations and the hard mask 204, critical dimension 216 of the contact opening 214 can be precisely controlled. In particular, for the second etching operation, the etching selectivity ratio between the hard mask 204 and the dielectric layer 202 for a flat surface can be as high as 1:20. Even in the comer regions, the etching selectivity ratio can still be 1:6. In brief, the hard mask 204 is able to provide very good protection to the dielectric layer 202 during the second etching operation.

In summary, one major innovation of this invention is the formation of a hard mask layer over a dielectric layer before the formation of a patterned photosensitive layer. Two different etching operations using different etchants, flow rates and pressures are carried out to form the contact opening. Because of the high etching selectivity ratio between the hard mask and the dielectric layer in the second etching operation, the hard mask layer is still capable of protecting the dielectric layer outside the edge of the contact opening region even after a portion of the photosensitive layer is removed to expose the hard mask layer. Due to protection by the hard mask layer, the critical dimension near the top of the contact opening can be precisely controlled. Hence, leakage and bridging problems between neighboring devices are greatly reduced.

Since the dielectric layer is well protected by the hard mask layer, the processing window for the second stage etching operation is wider. In addition, although the method of forming a contact opening is illustrated in the embodiment, the scope of this invention is much wider. In fact, the method of this invention can be applied to control the critical dimension of any opening in a dielectric layer as long as the opening is formed by patterning a photosensitive layer followed by etching.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for controlling a critical dimension of a contact opening in a dielectric layer, comprising:
providing a substrate;
forming a dielectric layer over the substrate;
forming a hard mask layer over the dielectric layer;
forming a photosensitive layer over the hard mask layer, wherein the photosensitive layer is further patterned to expose the hard mask layer inside a desired contact opening region;
performing a first etching operation to remove the hard mask layer within the contact opening region so that the dielectric layer within the contact opening region is exposed; and
performing a second etching operation to remove the exposed dielectric layer within the contact opening region so that a contact opening having a desired critical dimension near the top is formed.

2. The method of claim 1, wherein the step of forming the dielectric layer includes depositing oxide material to form an oxide layer.

3. The method of claim 1, wherein the material for forming the hard mask layer is either titanium or titanium nitride.

4. The method of claim 1, wherein the step of forming the hard mask layer includes depositing titanium and titanium nitride in sequence to form a titanium/titanium nitride composite layer.

5. The method of claim 4, wherein the titanium nitride layer has a thickness of about 200 Å to 400 Å.

6. The method of claim 4, wherein the titanium layer has a thickness of about 100 Å to 200 Å.

7. The method of claim 1, wherein the second etching operation includes performing an anisotropic etching operation.

8. The method of claim 7, wherein the second etching operation is carried at a pressure of between about 40 and 60 mT using gaseous reactants that include CH₂F₂ with a flow rate of about 30 to 60 sccm, nitrogen with a flow rate of about 30 to 70 sccm, and oxygen with a flow rate of about 50 to 200 sccm.

9. A method for forming a contact opening, comprising the steps of:
providing a substrate having a dielectric layer thereon;
forming a hard mask layer over the dielectric layer, wherein the hard mask layer is patterned to expose a portion of the dielectric layer; and
performing an anisotropic etching using the hard mask layer as an etching mask to remove a portion of the dielectric layer so that a contact opening is formed in the dielectric layer.

10. The method of claim 9, wherein the step of forming the dielectric layer includes depositing oxide material to form an oxide layer.

11. The method of claim 9, wherein a material for forming the hard mask layer is titanium.

12. The method of claim 9, wherein a material for forming the hard mask layer is titanium nitride.

13. The method of claim 9, wherein the step of forming the hard mask layer includes depositing titanium and titanium nitride in sequence to form a titanium/titanium nitride composite layer.

14. The method of claim 12, wherein the titanium nitride layer has a thickness of about 200 Å to 400 Å and the titanium layer has a thickness of about 100 Å to 200 Å.

15. The method of claim 9, wherein the second etching operation is carried at a pressure of between about 40 and 60 mT using gaseous reactants that include CH₂F₂ with a flow rate of about 30 to 60 sccm, nitrogen with a flow rate of about 30 to 70 sccm, and oxygen with a flow rate of about 50 to 200 sccm.

16. The method of claim 14, wherein the hard mask layer has a smaller etching rate than the dielectric layer in the anisotropic etching operation.

17. A method for forming a contact opening, comprising the steps of:
providing a substrate;
forming an oxide layer over the substrate;
forming a titanium layer over the oxide layer;
forming a titanium nitride layer over the titanium layer;
forming a photosensitive layer over the titanium nitride layer, wherein the photosensitive layer is further patterned to expose a portion of the titanium nitride layer inside a desired contact opening region;
performing a first etching operation with a first set of etching parameters to remove a portion of the titanium nitride layer and the titanium layer inside the contact opening region; and
performing a second etching operation with a second set of etching parameters to remove the oxide layer inside the contact opening region so that a contact opening is formed, wherein a width of the contact opening is identical to a width of the contact opening region at a top surface of the titanium nitride layer marked out by the photosensitive layer.

18. The method of claim 16, wherein the titanium nitride layer has a thickness of about 200 Å to 400 Å and the titanium layer has a thickness of about 100 Å to 200 Å.

19. The method of claim 16, wherein the second etching operation is carried out at a pressure of between about 40 and 60 mT using gaseous reactants that include CH₂F₂ with a flow rate of about 30 to 60 sccm, nitrogen with a flow rate of about 30 to 70 sccm, and oxygen with a flow rate of about 50 to 200 sccm.

20. The method of claim 16, wherein the first etching operation is carried at a pressure of between about 10 and 30 mT using gaseous reactants that include C₄F₈ with a flow rate of about 10 to 30 sccm, nitrogen with a flow rate of about 10 to 40 sccm, and argon with a flow rate of about 200 to 500 sccm.
